(19) United States
(12) Patent Application Publication
(10) Pub. No.: US 2014/0038310 A1
(43) Pub. Date: Feb. 6, 2014

(54) MAGNETIC RANDOM ACCESS MEMORY WITH SYNTHETIC ANTIFERROMAGNETIC STORAGE LAYERS

(71) Applicant: David W. Abraham, Croton, NY (US)

(72) Inventor: David W. Abraham, Croton, NY (US)

(73) Assignee: INTERNATIONAL BUSINESS MACHINES CORPORATION, Armonk, NY (US)

(21) Appl. No.: 13/566,137

(22) Filed: Aug. 3, 2012

Related U.S. Application Data
(63) Continuation of application No. 13/562,861, filed on Jul. 31, 2012.

(51) Int. Cl. H01L 43/10

(52) U.S. Cl. 438/3; 257/E43.005

(57) ABSTRACT

A synthetic antiferromagnetic device includes a reference layer, a magnesium oxide spacer layer disposed on the reference layer, a cobalt iron boron layer disposed on the magnesium oxide spacer layer, and a first ruthenium layer disposed on cobalt iron boron layer, the first ruthenium layer having a thickness of approximately 0 Å to 32 Å.

### CROSS REFERENCE TO RELATED APPLICATIONS

This application is a continuation of U.S. patent application Ser. No. 13/562,861 filed Jul. 31, 2012, the contents of which are incorporated herein by reference thereto.

### BACKGROUND

The present invention relates to magnetic random access memory devices, and more specifically, to a high anneal temperature synthetic antiferromagnetic (SAF) freelayer for magnetic random access memory (MRAM) devices.

SAF storage layers are implemented in magnetic random access memory devices (MRAM) with certain advantages. For example, it appears that higher activation energy can be obtained for equivalent switching currents when using a SAF structure versus a simple single free layer. Currently, the results in this example are obtained with low-temperature annealing and processing. However, for many semiconductor applications (particularly for embedded memory applications) it is important that the process be compatible with existing CMOS fabrication requirements. In practice, this means that the MRAM device must be able to withstand high temperature annealing and processing, with temperatures in the range of 400° C. for 1 hour total exposure time. Currently, it is also possible to fabricate SAF structures, which survived 400° C. anneals, demonstrating strong coupling in the SAF. Spin torque switching was observed up to 350 C anneal temperatures. However, the current density can be large and the activation energy reported was only 62 kT. For applications in MRAM, an activation energy of at least 80 kT is typically required.

### SUMMARY

Exemplary embodiments include a method of fabricating a synthetic antiferromagnetic device, the method including, depositing a magnesium oxide spacer layer on a reference layer, depositing a cobalt iron boron layer on the magnesium oxide spacer layer, and depositing a first ruthenium layer on cobalt iron boron layer, the first ruthenium layer having a thickness of approximately 0 Å to 18 Å.

Additional exemplary embodiments include a method of fabricating a synthetic antiferromagnetic device, the method including depositing a spacer layer on a reference layer, depositing a storage layer on the spacer layer, the storage layer including a ruthenium layer having a thickness of approximately 0 Å to 32 Å and a cap layer disposed on the storage layer.

Further exemplary embodiments include a method of fabricating a synthetic antiferromagnetic device, the method including depositing a reference layer on a substrate, depositing a magnesium oxide spacer layer on the reference layer, depositing an iron layer on the magnesium oxide spacer layer, depositing a cobalt iron boron layer on the iron layer, depositing a first ruthenium layer on the cobalt iron boron layer, the first ruthenium layer having a thickness of approximately 2 Å or approximately 9 Å, depositing a cobalt iron layer on the first ruthenium layer, depositing a second ruthenium layer on the cobalt iron layer, depositing a tantalum nitride layer on the second ruthenium layer, coupling a bottom contact to the substrate, and coupling a top contact to the tantalum nitride layer, wherein the iron layer, the cobalt iron boron layer, the first ruthenium layer and the cobalt iron layer form a reference layer.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 illustrates an exemplary SAF device;

FIG. 2 illustrates exemplary SAF devices; and

FIG. 3 illustrates a SAF fabrication method in accordance with exemplary embodiments.

### DETAILED DESCRIPTION

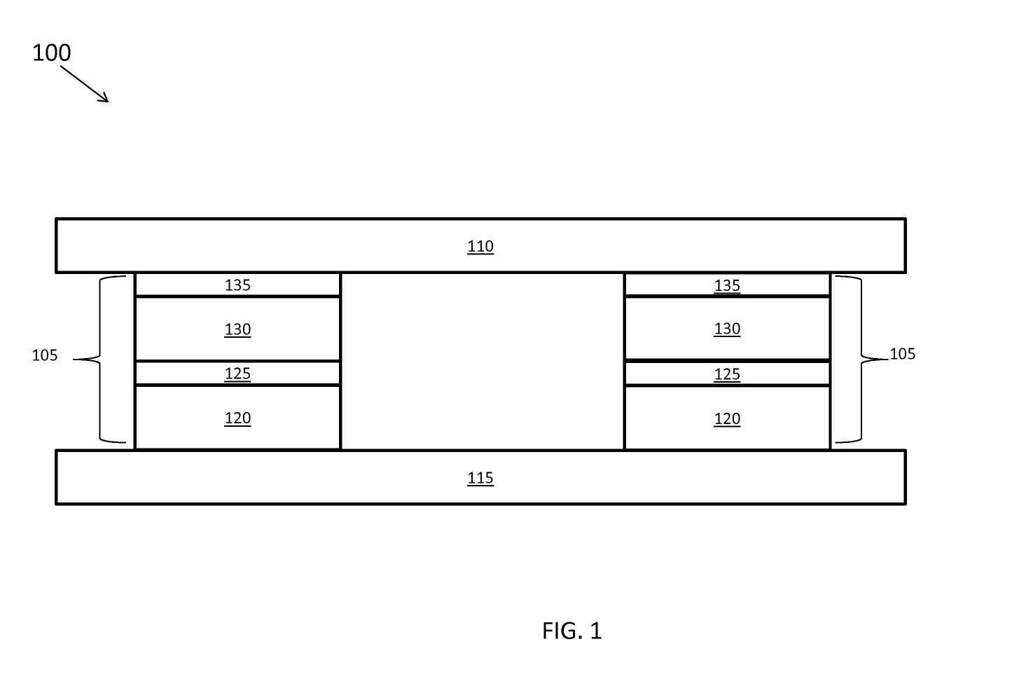

FIG. 1 illustrates an exemplary a SAF device 100 that includes high anneal temperature SAF storage (free) layers for magnetic random access memory devices. The device illustrates two SAF devices 105, although it will be appreciated that additional or fewer SAF devices are contemplated in other exemplary embodiments. In addition, the devices can be an unpatterned series of thin films. The device 100 includes a top contact 110 and a bottom contact 115 coupled to the SAF devices 105.

In exemplary embodiments, each of the SAF devices 105 includes a reference (pinned or non-pinned) layer 120 coupled to the bottom contact 115. In exemplary embodiments, the reference layer 120 can be any standard reference layer to provide a reference electrode. The SAF devices 105 further include a spacer layer 125 disposed on the reference layer 120 and a storage layer 130 disposed on the spacer 125. The SAF devices 105 further include a cap layer 135 disposed between the storage layer 130 and the top contact 110.

In exemplary embodiments, the SAF devices 105 described herein incorporate the storage layer 130, which combines both thermal stability at 400° C. for the required period and switching with appropriately low switching currents, device resistance, activation energy and coercivity to allow proper functioning in an MRAM device. As further described herein, the implementation of ruthenium (Ru) in the storage layer at various thicknesses provides the thermal stability and target operating parameters in the final MRAM device.

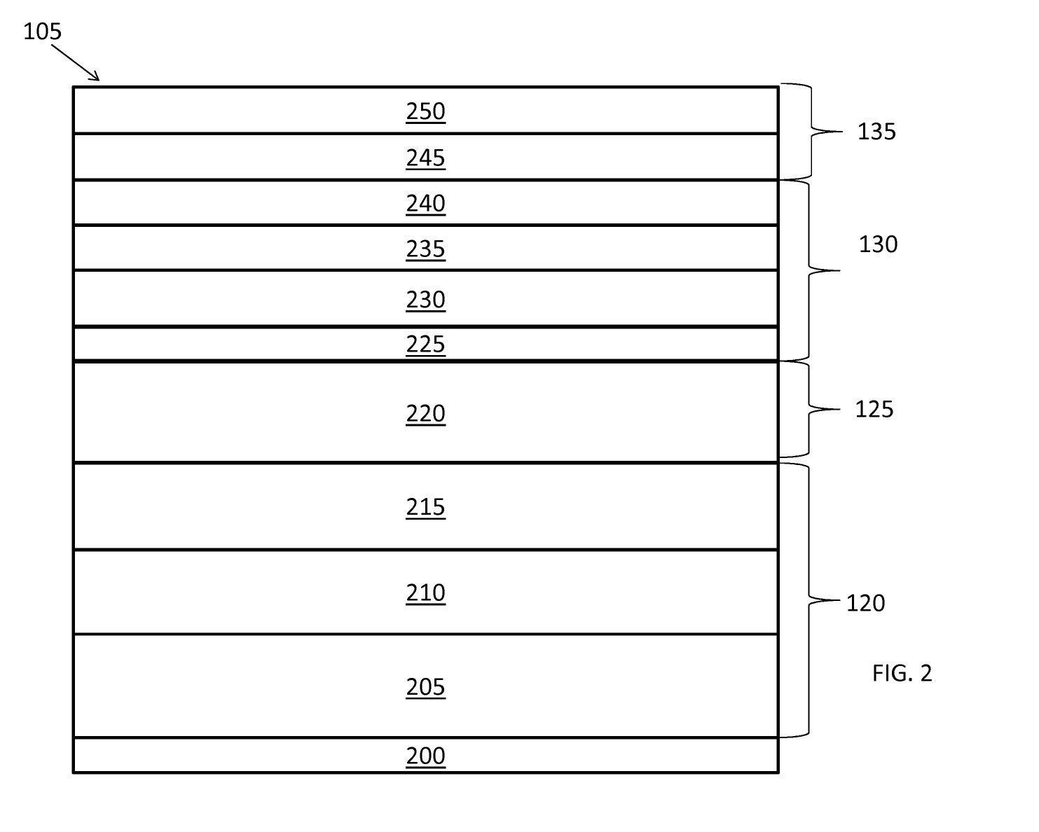

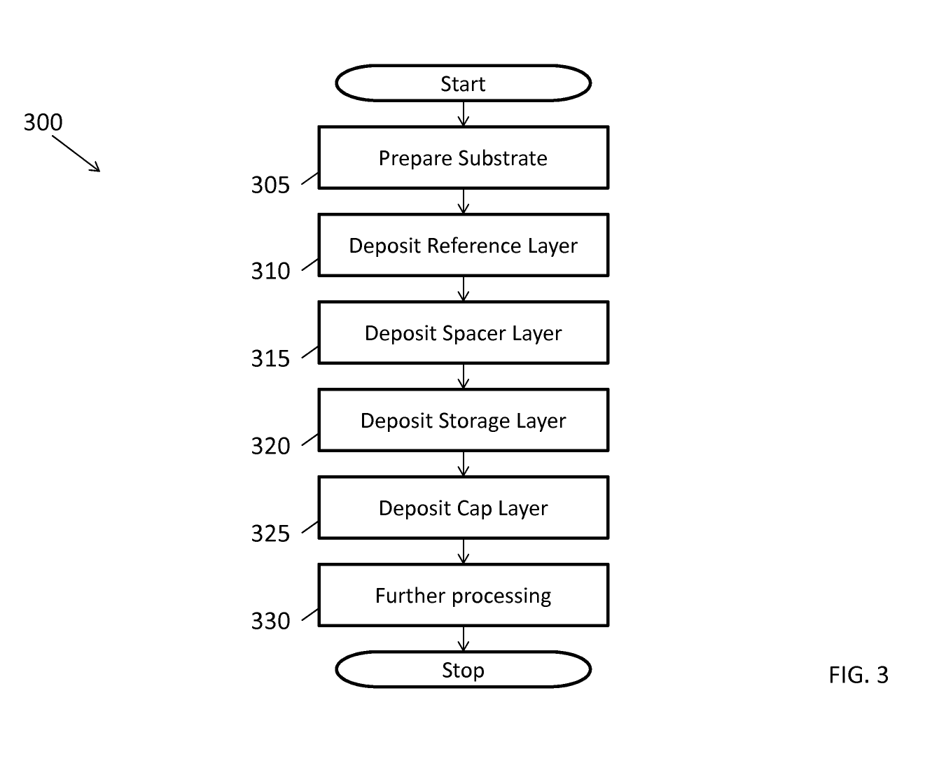

FIG. 2 illustrates the SAF devices 105 in further detail. FIG. 3 illustrates a SAF fabrication method 300 in accordance with exemplary embodiments. At block 305, the substrate 200 is prepared. The substrate 200 can be silicon (Si). In order to attain magnetic tunnel junction (MTJ) performance in the final MRAM device, preparation of the substrate 200 includes attaining atomic-scale flatness over areas of the order of the size of an MTJ. Atomic scale flatness reduces dipolar magnetic coupling effects and makes for a well-controlled MRAM device. Substrates for the short-loop process are thus generally prepared either with a careful silicon wafer oxidation/cleaning or with the deposition of a dielectric such as silicon nitride (SiN) on the substrate 200, followed by a chemical-mechanical planarization (CMP) step to smooth the surface.

At block 310, the reference layer 120 is deposited. As described herein, the reference layer 120 can include any standard reference layer, which can include a seed layer 205 to promote polycrystalline growth. In the example of FIG. 2, the seed layer 2-5 can include tantalum (Ta) or tantalum nitride (TaN). In exemplary bodiments, depending on the implementation, the reference layer can then further include a variety of other layers including but not limited to an antiferromagnet for strong pinning of the reference layer (e.g., PtMn or IrMn), and an antiferromagnetically exchange-biased pair of ferromagnets (e.g., CoFe/Ru/CoFe). In the example of FIG. 2 a Ru layer 210 is deposited on the seed layer 205, and a cobalt iron boron (CoFeB) layer 215 is deposited on the Ru layer 210, providing a single ferromagnet on the seed layer 205.

At block 315, the spacer layer 125 is deposited on the reference layer 12 In exemplary embodiments, the spacer layer 125 is a suitable insulating tunnel barrier (e.g., aluminum oxide (Al₂O₃) or magnesium oxide (MgO)). In the example in FIG. 2, the spacer layer is MgO.

At block 320, the storage layer 130 is deposited on the spacer layer 125. In the example in FIG. 2, an Fe layer 225 is deposited on the spacer layer 125, followed by a deposition of a CoFeB layer 230, followed by deposition of an Ru layer 235, and followed by a deposition of a CoFe layer.

At block 325, a suitable cap layer 135 is deposited on the storage layer 130. In the example shown in FIG. 2, the cap layer 135 includes a Ru layer 245 deposited on the storage layer 130 followed by a deposition of a TaN layer 250.

At block 330, further semiconductor processing can be implemented. For example, the SAF device 100 can be encapsulated in a dielectric. The encapsulation of the SAF device 100 protects the SAF device 100 while at the same time forming the environment in which the attachment of the top and bottom contacts 110, 115 can be implemented. The choice of encapsulation is determined from three requirements: a) it must not damage the SAF devices 100; b) it must adhere well to the substrate 200; and c) it should closely emulate the interlayer dielectrics (ILDs) that would be used in a fully integrated wafer processes. For example, damage to the MTJs can arise from chemical interactions and thermal stress. Standard semiconductor-industry dielectrics typically are deposited or cured at temperatures around 400° C., whereas degradation in submicron MTJs can set in at temperatures below 350° C. Thus, a major challenge to the integrator of MRAM devices is the development and utilization of suitable low temperature dielectrics. However, it will be appreciated that the SAF device can withstand the high anneal temperatures discussed above. Adhesion of the dielectric to the substrate can be particularly problematic given the characteristics of the magnetic films being used. Noble-metal-containing antiferromagnets can be particularly difficult to adhere to, and, if exposed by the etching used for MTJ patterning, can require specialized surface-cleaning or surface-preparation techniques to promote adhesion to the encapsulating dielectric. The dielectric thickness is chosen such that it will be thick enough to provide the environment for the wiring level above the MTJs.

Other semiconducting fabrication processes can include planarization. To facilitate industry standard damascene copper wiring, the wafers generally undergo a gentle dielectric CMP process at this stage. The purpose of the CMP is to remove topography from the surface that is caused by the underlying MTJs. This step is also the first check of the adhesion of the dielectrics to the underlying metal films, as well as the cohesion of the metal films to each other. If the encapsulating dielectrics are suitably planarizing in their deposition, this CMP planarization step can be eliminated fur faster turnaround time and potentially higher yield.

Patterning of the MTJ introduces device-to-device isolation in the counter-electrode (the conductive portion of the storage layer 130 above the spacer layer 125), but maintains electrical continuity between all devices in the base electrode (the conductive portion of the reference layer 120 below the spacer layer 125). Often negligible in fully integrated wafers, the resistance of the base electrode after MTJ patterning is germane to the short loop. The use of a continuous planar base electrode incurs additional measurement error at final electrical testing if the base electrode possesses a high sheet resistance. Subject to the constraint of emulating the stack used in fully functional wafers, the magnetic stack of the short loop will therefore include thick or low resistivity films beneath the tunnel barrier. A commonly used, straightforward approach to patterning the MTJs is through the use of a conducting hard mask. The conducting mask is later utilized as a self-aligned stud bridging the conductive MT wiring to the active magnetic films in the device. Such a processing scheme is among the simplest and fastest ways of creating and contacting the MTJs, making it an ideal approach for use in the short loop. Choices for the hard mask are numerous, with necessary characteristics being etchability and a resistance that is negligible when compared with MTJ resistance. Refractory materials commonly used in the semiconductor industry such as Ta, TaN, and TiN are suitable masks for MTJ patterning. The MTJ shapes are defined in the hard mask by transfer from a first photomask level in a process such as the following: apply resist/expose and develop/reactive ion etching (RIE) through hard mask/strip resist. The pattern is further transferred downward to penetrate to (or through) the tunnel barrier, leaving behind a low-resistance base layer which covers the entire wafer.

After completion of the steps for MRAM development (e.g., layer formation, patterning, and encapsulation), the wiring (e.g., applying the bottom and top contacts 110, 115) is instituted in the simplest manner consistent with the available tooling. Relying on well-established semiconductor-industry techniques, a photomask defined trench is etched into the dielectric with RIE, to be filled with a liner and high-conductivity copper. The depth of the trench is sufficient to expose a portion of the conducting hard-mask stud (the counter-electrode), while not so deep as to create a short circuit to the planar base electrode. Endpointing during the trench RIE can facilitate the proper choice of trench depth even for relatively thin hard-mask films. After the trench etching and a suitable cleaning step, the wiring liner film is deposited, along with a thin copper seed layer. This deposition is followed by the electroplating of copper to completely fill the trench and provide enough overburden so that the ensuing CMP step will planarize the metal coincident with the surface of the dielectric. This final CMP step can be aggressive enough to cause shear failure of the films on the wafers, and care must be taken to prevent such delamination. A post-polish cleaning of the wafers is the final preparation step before electrical testing.

As described herein, the implementation of ruthenium (Ru) in the storage layer at various thicknesses provides the thermal stability and target operating parameters in the final MRAM device. A combination of the Ru in the storage layer 130 and particular compositions of the CoFeB layer 230 result in proper operation of the SAF device 100 with a combination of best exchange coupling and thermal stability at the high anneal/curing temperatures (e.g., 375° C.-400° C.).

### EXAMPLE

In one embodiment, the best exchange coupling between the spacer layer and the storage layer 130, with highest thermal stability during the different curing/annealing fabrication steps, occurred for the composition as now described. The TaN layer 205 is 10 angstroms (Å), the Ru layer 210 is 20 Å. The CoFeB layer 215 is 2 Å and the specific composition is Co₆₀Fe₂₀B₂₀. It can be appreciated that the CoFeB layer can be replaced with a reference layer and is described here for illustrative purposes. The spacer layer 125 of MgO is formed by depositing 5.5 Å of Mg following by a 60 second exposure to oxygen under a rate of 200 standard centimeter cube per minute (sccm). It can be appreciated that any Mg thickness with natural oxidation can be implemented. Another layer of 3 Å of Mg is deposited followed by a 60 second exposure to oxygen under a rate of 50 sccm. Finally another layer of 3 Å of Mg is deposited. The storage layer 130 is then deposited with 5 Å of the Fe layer 225. The CoFeB layer 230 is then deposited with 15 A of the composition Co₂₀Fe₆₀B₂₀. The Ru layer 235 is then deposited with Ru at a thickness ranging from 0 Å to 32 Å. The CoFe layer 240 is 15 Å of the specific composition Co₇₅Fe₂₅. Finally the cap layer 135 includes the Ru layer 245 at 20A and the TaN layer 250 at 40 Å. It has been determined that the thickness of the Ru layer 235 (e.g., 20 Å) determines the best exchange coupling between the spacer layer and the storage layer 130, with highest thermal stability during the different curing/annealing fabrication steps.

The exemplary embodiments described herein illustrate magnetic coupling of the Ru layer 235 for thicknesses of the Ru layer 235 up to 18 Å-32 Å. A significant increase of coupling (approximately 500 Oe for 18 Å and about 150-200 Oe for 32 Å) occurs at approximately 9 Å of Ru for the Ru layer 235. The coupling occurs for anneals at 375° C.-400° C. It can be appreciated that coupling occurs much lower temperatures that coupling not significantly changed when anneal temperature goes higher, as much as 400 C].

As such, several factors are important for proper operation of the SAF device 100 structure. First, strong Ru coupling peaks occur at approximately 18 Å of Ru and at approximately 20 Å Ru, and also about 32 Å for the Ru layer 235. Secondly, the specific stack structure described in the example herein with the Ru thicknesses of the Ru layer 235 is a composition that provides the strong exchange coupling and thermal stability. Third, the CoFeB layer 230 can be either Co₆₀Fe₂₀B₂₀, or Co₂₀Fe₆₀B₂₀. However, it has been shown that Co₂₀Fe₆₀B₂₀ demonstrates slightly less thermal stability.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A method of fabricating a synthetic antiferromagnetic (SAF) device, the method comprising:
depositing a magnesium oxide (MgO) spacer layer on a reference layer;
depositing a cobalt iron boron (CoFeB) layer on the MgO spacer layer; and
depositing a first ruthenium (Ru) layer on the CoFeB layer, the first Ru layer having a thickness of approximately up to 18 angstroms (Å).

2. The method as claimed in claim 1 further comprising depositing a CoFe layer on the first Ru layer.

3. The method as claimed in claim 2 further comprising depositing a cap layer on the CoFe layer.

4. The method as claimed in claim 3 wherein the cap layer comprises:
a second Ru layer disposed on the CoFe layer; and
a tantalum nitride (TaN) layer disposed on the second Ru layer.

6. The method claimed in claim 2 wherein the MgO spacer layer is magnetically coupled to the CoFeB layer, the first Ru layer and the CoFe layer after the device is subject to anneal temperatures of about 375° C. to 400° C.

7. The method as claimed in claim 1 wherein the first Ru layer is approximately 9 Å.

8. The method as claimed in claim 7 wherein the MgO layer is magnetically coupled to the CoFeB layer, the first Ru layer and the CoFe layer at about 500 Oersteds (Oe).

9. The method as claimed in claim 1 wherein the CoFeB layer is Co₆₀Fe₂₀B₂₀.

10. The method as claimed in claim 1 wherein the CoFeB layer is Co₂₀Fe₆₀B₂₀.

11. A method of fabricating a synthetic antiferromagnetic (SAF) device, the method comprising:
a reference layer;
depositing a spacer layer on a reference layer;
depositing a storage layer on the spacer layer, the storage layer including a ruthenium (Ru) layer having a thickness of approximately up to 32 angstroms (Å); and
depositing a cap layer on the storage layer.

12. The method as claimed in claim 11 wherein the first Ru layer is approximately 2 Å.

13. The method as claimed in claim 12 wherein the reference layer is magnetically coupled to the spacer layer at about 100 Oersteds (Oe).

14. The method as claimed in claim 11 wherein the first Ru layer is approximately 9 Å.

15. The method as claimed in claim 12 wherein the reference layer is magnetically coupled to the spacer layer at about 150-200 Oe.

16. The method as claimed in claim 11 further comprising depositing a cobalt iron boron (CoFeB) layer on the spacer layer.

17. The method as claimed in claim 16 wherein the Ru layer is disposed on the CoFeB layer.

18. The method as claimed in claim 15 further comprising depositing a CoFe layer on the Ru layer.

19. A method of fabricating a synthetic antiferromagnetic (SAF) device, the method comprising:
depositing a reference layer disposed on a substrate;
depositing a magnesium oxide (MgO) spacer layer on the reference layer;
depositing an iron (Fe) layer on the spacer layer;
depositing a cobalt iron boron (CoFeB) layer on the Fe layer;
depositing a first ruthenium (Ru) layer on the CoFeB layer, the first Ru layer having a thickness of approximately 2 angstroms (Å) or approximately 9 Å;
depositing a CoFe layer on the first Ru layer;
depositing a second Ru layer don the CoFe layer;
depositing a tantalum nitride (TaN) layer on the second Ru layer;
coupling a bottom contact to the substrate; and
coupling a top contact to the TaN layer,
wherein the Fe layer, the CoFeB layer, the first Ru layer and the CoFe layer form a reference layer.

20. The method as claimed in claim 19 wherein exchange coupling between the MgO spacer layer and the reference layer is higher for the first Ru layer thickness being 9 Å compared to the first Ru layer thickness being 2 Å.
